(19) United States
(12) Patent Application Publication
(10) Pub. No.: US 2017/0162405 A1
(43) Pub. Date: Jun. 8, 2017

(54) SPIN CHUCK WITH HEATED NOZZLE ASSEMBLY

(71) Applicant: LAM RESEARCH AG, VILLACH (AT)

(72) Inventor: Andreas GLEISSNER, Dobriach (AT)

(73) Assignee: LAM RESEARCH AG

(21) Appl. No.: 14/960,072

(22) Filed: Dec. 4, 2015

(51) Int. Cl. H01L 21/67; H01L 21/687

(52) U.S. Cl. CPC H01L 21/67017; H01L 21/68764

(57) ABSTRACT

An apparatus for processing wafer-shaped articles comprises a process chamber and a spin chuck positioned inside the process chamber. The spin chuck is configured to hold a wafer-shaped article at a predetermined process position. A nozzle assembly extends into the process chamber such that a discharge end of the nozzle assembly faces the predetermined process position. The nozzle assembly is equipped with a heater that heats portions of the nozzle assembly located within the process chamber. Such heating may be performed, for example, to promote evaporation of liquid droplets from the nozzle assembly.

### BACKGROUND OF THE INVENTION

1. Field of the Invention

The invention relates generally to an apparatus for processing wafer-shaped articles, such as semiconductor wafers, and more particularly relates to such an apparatus comprising a spin chuck equipped with a heated nozzle assembly.

2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668.

Alternatively, a chuck in the form of a ring rotor adapted to support a wafer may be located within a closed process chamber and driven without physical contact through an active magnetic bearing, as is described for example in International Publication No. WO 2007/101764 and U.S. Pat. No. 6,485,531.

When process liquid is dispensed from above the wafer, drips from the nozzle after the completion of processing can damage the delicate device structures formed on the wafer surface. Techniques that have been conventionally used to prevent such drips include using suction in the dispensing nozzle upon completion of processing, equipping the nozzle with valves to prevent liquid flow, and mounting the nozzle assembly so that is can be moved to a standby position in which it does not overlie the wafer. These conventional solutions, however, may add undue complexity and cost to the apparatus, and/or are not sufficiently effective in preventing unwanted drips of process liquid onto the wafer surface.

### SUMMARY OF THE INVENTION

The present inventors have developed an improved apparatus for treatment of wafer-shaped articles, in which a spin chuck is equipped with a heated nozzle assembly.

Thus, in one aspect, the present invention relates to an apparatus for processing wafer-shaped articles, comprising a process chamber, and a spin chuck positioned inside the process chamber. The spin chuck is configured to hold a wafer-shaped article at a predetermined process position. A nozzle assembly extends into the process chamber such that a discharge end of the nozzle assembly faces the predetermined process position. The nozzle assembly is equipped with a heater that heats portions of the nozzle assembly located within the process chamber. Such heating may be performed, for example, to promote evaporation of liquid droplets from the nozzle assembly.

In preferred embodiments of the apparatus according to the present invention, the heater is a conductive heating element mounted within the nozzle assembly.

In preferred embodiments of the apparatus according to the present invention, exterior surfaces of the nozzle assembly that face the predetermined process position within the process chamber are hydrophilic.

In preferred embodiments of the apparatus according to the present invention, the exterior surfaces of the nozzle assembly that face the predetermined process position within the process chamber comprise a coating or surface treatment to confer to the exterior surfaces a water contact angle of less than 25° at 25° C. and 1 bar air.

In preferred embodiments of the apparatus according to the present invention, the nozzle assembly comprises ceramic nozzles at least partially disposed within the process chamber, wherein the ceramic is selected from the group consisting of alumina (Al₂O₃), silicon carbide, silicon and carbon.

In preferred embodiments of the apparatus according to the present invention, the ceramic is alumina.

In preferred embodiments of the apparatus according to the present invention, the exterior surfaces of the nozzle assembly comprising ceramic nozzles that face the predetermined process position within the process chamber comprise a coating or surface treatment to confer to the exterior surfaces a water contact angle of less than 25° at 25° C. and 1 bar air.

In preferred embodiments of the apparatus according to the present invention, the spin chuck comprises a plate disposed above the predetermined process position, the plate being affixed to the spin chuck for rotation therewith, the plate having a central opening through which the discharge end of the nozzle assembly passes, an annular clearance being defined between the central opening of the plate and the discharge end of the nozzle assembly.

In preferred embodiments of the apparatus according to the present invention, the plate and an upper part of the process chamber define a gas distribution chamber, and wherein the plate comprises plural openings formed in each of a central and a peripheral region thereof, thereby to supply process gas from the gas distribution chamber to a surface of a wafer-shaped article when held by the spin chuck.

In preferred embodiments of the apparatus according to the present invention, each of the plural openings has a cross-sectional area in a range from 0.3 to 2.0 mm², preferably from 0.5 to 1.5 mm², and more preferably from 0.7 to 1.2 mm².

In preferred embodiments of the apparatus according to the present invention, the plural openings includes at least 20 of the openings, more preferably at least 50 of the openings, and still more preferably at least 80 of the openings.

In preferred embodiments of the apparatus according to the present invention, the plate is domed such that a central region thereof is positioned farther from a wafer-shaped article when positioned on the spin chuck than a peripheral region thereof.

In preferred embodiments of the apparatus according to the present invention, the nozzle assembly comprises a liquid supply conduit and a gas supply conduit, each of the liquid supply conduit and the gas supply conduit opening at the discharge end of the nozzle assembly.

In preferred embodiments of the apparatus according to the present invention, the nozzle assembly comprises a peripheral gas supply conduit positioned above the plate and communicating with the annular clearance.

In preferred embodiments of the apparatus according to the present invention, the spin chuck is a magnetic rotor, the apparatus further comprising a magnetic stator mounted outside of the process chamber and surrounding the magnetic rotor.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is an explanatory cross-sectional side view of an apparatus according to a first embodiment of the invention;

FIG. 2 is a partial perspective view, partly in section, showing additional details of the embodiment of FIG. 1; and

FIG. 3 is a view like that of FIG. 2, showing an alternative embodiment of the apparatus according to the present invention.

### DETAILED DESCRIPTION OF PREFERRED EMBODIMENTS

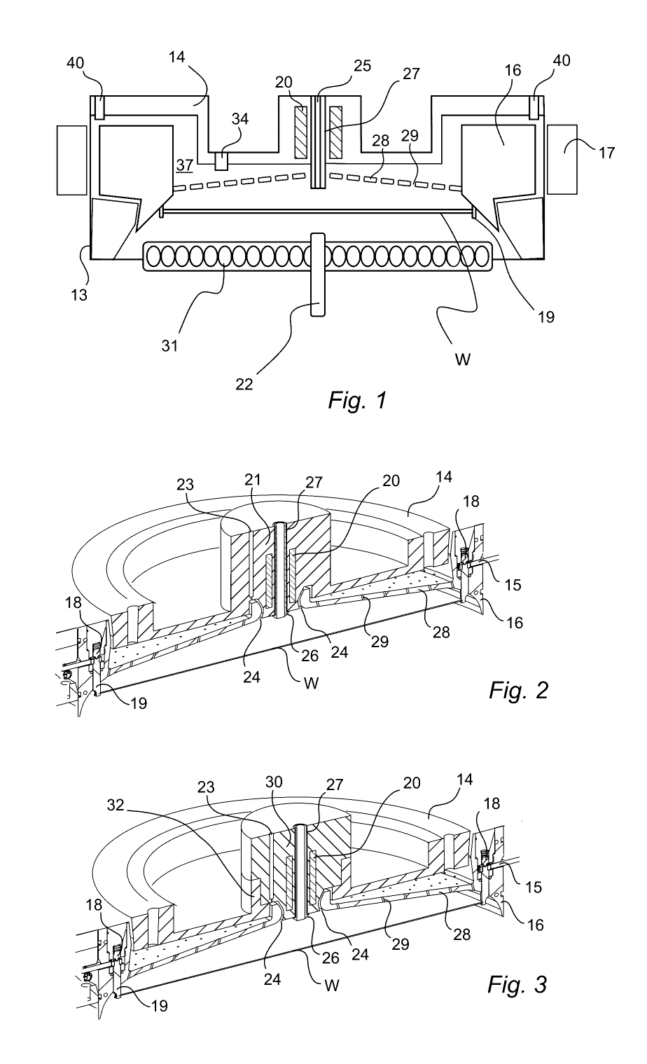

Referring now to FIG. 1, an apparatus for treating surfaces of wafer-shaped articles according to a first embodiment of the invention comprises a closed process chamber 13, in which is arranged an annular spin chuck 16. Spin chuck 16 is a magnetic rotor that is surrounded by a magnetic stator 17 positioned outside the chamber, so that the magnetic rotor is freely rotating and levitating within the chamber 13 without touching the chamber walls. The chamber 13 is closed at its upper end by lid 14 rigidly secured thereto.

Further structural details of such a magnetic rotor chuck are described, for example, in commonly-owned U.S. Pat. No. 8,646,767.

The annular spin chuck 16 has a circular series of downwardly-depending gripping pins 19, which releasably hold a wafer W during processing. A lower dispense unit 22 is provided so as to supply liquid and/or gas to the side of the wafer W that faces downwardly within chamber 13. A heater 31 is disposed within the chamber 13, so as to heat the wafer W to a desired temperature depending upon the process being performed. Heater 31 preferably comprises a multitude of blue LED lamps, whose radiation output tends to be absorbed preferentially by silicon wafers relative to the components of the chamber 13.

An upper dispense unit comprises an outer gas conduit 27 and an inner liquid conduit 25 arranged coaxially within the outer gas conduit 25. Conduits 25, 27 both traverse the lid 14, and permit liquid and gas to be supplied to the side of the wafer W that faces upwardly within chamber 13.

A gas showerhead is delimited at its lower side by an outlet plate 28. The outlet plate 28 comprises a multitude of discharge orifices 29, which permit process gas to pass out of the gas showerhead from the gas distribution chamber 37 to the region adjacent the upwardly facing side of the wafer W. The discharge orifices 29 in this embodiment each have a cross-sectional area in a range from 0.3 to 2.0 mm, preferably from 0.5 to 1.5 mm, and more preferably from 0.7 to 1.2 mm. There are preferably at least 20 orifices 29, and more preferably at least 80; even more preferably 300.

The gas distribution chamber 37 is supplied with process gas through a process gas supply conduit 34, which in turn communicates with a source of process gas (not shown), which in preferred embodiments is a gas containing ozone.

The outlet plate 28 is rigidly secured to the spin chuck 16, or formed in one piece therewith, and therefore rotates along with the spin chuck 16. On the other hand, the conduits 25, 27 are stationarily mounted in the lid 14 of chamber 13, and pass with a slight clearance through a central opening formed in the plate 28.

Lid 14 incorporates a second heater 20 that is positioned within the nozzle assembly comprising conduits 25, 27. Heater 20 is preferably an electrical resistance heater that serves to heat surfaces of the nozzle assembly that face inwardly of the process chamber 13.

Additional gas conduits 40 are provided near the outer periphery of chamber 13, and direct a purge gas such as N₂ into the gap defined between the outer periphery of spin chuck 16 and the surrounding cylindrical wall of chamber 13. Gas from nozzles 40 also forms a boundary such that process gas supplied from nozzle 34 is confined with distribution chamber 37.

As shown in FIG. 2, the nozzle assembly 21 may be formed integrally with the chamber lid 14. Plate 28 in this embodiment is formed integrally with the spin chuck 16. The lower end of nozzle assembly 21 passes through a central opening in plate 28, and an annular gap 24 is defined between these two components.

Nozzle assembly 21 also includes a third nozzle 23, which directs gas into or adjacent this annular gap 24.

The spin chuck 16 also includes the gripping pins 19 described above, as well as needle bearings 18 that urge the pins 19 downwardly so that gear wheels at the upper ends of the pins 19 remain in continuous meshing engagement with the toothed sectors of a common ring gear 15, as described for example in commonly-owned U.S. Pat. No. 8,646,767 and U.S. published patent application no. 2015/0008632.

Heater 20, which in this embodiment is a conductive heating element mounted within the nozzle assembly 21, serves to heat portions of the nozzle assembly 21 that are located within the process chamber 13, so as to promote evaporation of liquid droplets from the nozzle assembly.

That evaporation is also promoted if the surfaces such as surface 26 of nozzle assembly 21 that face into the chamber 13 are hydrophilic, as any process liquid droplets will thus tend to spread out over those surfaces and evaporate more readily.

The nozzle assembly 21 may be made in whole or in part from ceramic materials, with preferred ceramic materials being alumina (Al₂O₃), silicon carbide and carbon. The ceramic parts of the nozzle assembly 21 may be fabricated by any suitable technique, including, without limitation, 3D printing.

When the nozzle assembly includes ceramic components, then preferably at least those surfaces facing into chamber 13 are provided with a surface coating or a surface treatment so as to render them hydrophilic. A preferred hydrophilic surface is one which displays a water contact angle of less than 25° at 25° C. and 1 bar air.

In FIG. 3, the nozzle assembly 30 is formed separately from the lid 14 of chamber 13, and fitted to a receiving flange 32 formed on the lid 14 with appropriate connectors and seals (not shown). The embodiment of FIG. 3 is otherwise as described in connection with FIG. 2.

In use, heater 20 is preferably activated either before or during processing in which a process liquid is dispensed through the nozzle 27, so that the surfaces 26 will have reached the desired temperature at the conclusion of processing. Heater 20 then remains activated for a time sufficient to evaporate any droplets of process liquid remaining on the surfaces 26. Heater 20 may also be provided with two or more power levels, so that, for example, the surfaces may be preheated to a first, lower temperature during dispensing of a process liquid through the nozzle 27, and thereafter heated to a second, higher temperature after the dispensing of process liquid through nozzle 27 has concluded.

While the present invention has been described in connection with various preferred embodiments thereof, it is to be understood that those embodiments are provided merely to illustrate the invention, and that the invention is not limited to those embodiments, but rather includes that which is encompassed by the true scope and spirit of the appended claims.

What is claimed is:

1. An apparatus for processing wafer-shaped articles, comprising:
a process chamber;
a spin chuck positioned inside said process chamber, said spin chuck being configured to hold a wafer-shaped article at a predetermined process position; and
a nozzle assembly that extends into said process chamber such that a discharge end of said nozzle assembly faces the predetermined process position;
said nozzle assembly comprising a heater that heats portions of said nozzle assembly located within said process chamber.

2. The apparatus according to claim 1, wherein said heater is a conductive heating element mounted within said nozzle assembly.

3. The apparatus according to claim 1, wherein exterior surfaces of said nozzle assembly that face said predetermined process position within said process chamber are hydrophilic.

4. The apparatus according to claim 3, wherein the exterior surfaces of the nozzle assembly that face said predetermined process position within said process chamber comprise a coating or surface treatment to confer to said exterior surfaces a water contact angle of less than 25° at 25° C. and 1 bar air.

5. The apparatus according to claim 1, wherein said nozzle assembly comprises ceramic nozzles at least partially disposed within said process chamber, wherein the ceramic is selected from the group consisting of alumina (Al₂O₃), silicon carbide, silicon and carbon.

6. The apparatus according to claim 5, wherein the ceramic is alumina.

7. The apparatus according to claim 5, wherein the exterior surfaces of said nozzle assembly comprising ceramic nozzles that face said predetermined process position within said process chamber comprise a coating or surface treatment to confer to said exterior surfaces a water contact angle of less than 25° at 25° C. and 1 bar air.

8. The apparatus according to claim 1, wherein said spin chuck comprises a plate disposed above said predetermined process position, said plate being affixed to the spin chuck for rotation therewith, said plate having a central opening through which said discharge end of said nozzle assembly passes, an annular clearance being defined between the central opening of said plate and said discharge end of said nozzle assembly.

9. The apparatus according to claim 8, wherein said plate and an upper part of said process chamber define a gas distribution chamber, and wherein said plate comprises plural openings formed in each of a central and a peripheral region thereof, thereby to supply process gas from said gas distribution chamber to a surface of a wafer-shaped article when held by said spin chuck.

10. The apparatus according to claim 9, wherein each of said plural openings has a cross-sectional area in a range from 0.3 to 2.0 mm².

11. The apparatus according to claim 9, wherein said plural openings includes at least 20 of said openings.

12. The apparatus according to claim 8, wherein said plate is domed such that a central region thereof is positioned farther from a wafer-shaped article when positioned on said spin chuck than a peripheral region thereof.

13. The apparatus according to claim 1, wherein said nozzle assembly comprises a liquid supply conduit and a gas supply conduit, each of said liquid supply conduit and said gas supply conduit opening at said discharge end of said nozzle assembly.

14. The apparatus according to claim 8, wherein said nozzle assembly comprises a peripheral gas supply conduit positioned above said plate and communicating with said annular clearance.

15. The apparatus according to claim 1, wherein said spin chuck is a magnetic rotor, said apparatus further comprising a magnetic stator mounted outside of said process chamber and surrounding said magnetic rotor.
